(19) United States
(12) Patent Application Publication
(10) Pub. No.: US 2025/0349343 A1
(43) Pub. Date: Nov. 13, 2025

(54) 3D MEMORY DEVICE WITH LOCAL COLUMN DECODING

(71) Applicant: Rambus Inc., San Jose, CA (US)

(72) Inventors: Thomas Vogelsang, Jericho, VT (US); Brent Steven Haukness, Sunnyvale, CA (US); Torsten Partsch, Raleigh, NC (US)

(21) Appl. No.: 18/869,501

(22) PCT Filed: May 25, 2023
(86) PCT No.: PCT/US2023/023505

§ 371 Date: Nov. 26, 2024

Related U.S. Application Data
(60) Provisional application No. 63/348,087, filed on Jun. 2, 2022.

(51) Int. Cl. G11C 11/408; G11C 11/4076; G11C 11/4096

(52) U.S. Cl. CPC G11C 11/4087; G11C 11/4076; G11C 11/4096

(57) ABSTRACT

A 3D memory device includes a plurality of mats that each include a memory array stacked over logic circuitry supporting operations of the memory array. The logic circuitry include a local column decoder under the memory array for selecting one or more local column select lines associated with a memory operation. The logic circuitry furthermore includes one or more selectable global array data bus redrivers for receiving global data signals from a set of global data signal buses, selecting one of the global data signal buses, and amplifying signals between the selected global data signal bus and a local data signal bus that communicates the data signals to and from the memory array. The 3D memory device supports concurrent sub-page accesses which may be interleaved for efficient memory operations.

### BACKGROUND

Memory devices such as Dynamic Random-Access Memory (DRAM) typically include an array of memory cells and supporting logic circuitry for facilitating memory operations. Traditional memory devices include a single layer architecture that includes the supporting logic circuitry in peripheral regions around the memory cell array. Three-dimensional (3D) memory architectures may include multiple layers of memory cells that achieve increased memory capacity without expanding its footprint.

### BRIEF DESCRIPTION OF THE DRAWINGS

The teachings of the embodiments herein can be readily understood by considering the following detailed description in conjunction with the accompanying drawings.

FIG. 1 is an example architecture for a 3D memory device.

FIG. 2A is a planar view of an example architecture of a mat for a 3D memory device.

FIG. 2B is a cross-sectional view of an example architecture of a 3D memory device.

FIG. 3 is a planar view of an example layout for a block of mats in a 3D memory device.

FIG. 4 is an example structure of a memory array in a 3D memory device.

FIG. 5 is a first example architecture of a logic layer of a mat in a 3D memory device.

FIG. 6 is a second example architecture of a logic layer of a mat in a 3D memory device.

FIG. 7 is a third example architecture of a logic layer of a mat in a 3D memory device.

FIG. 8 is an example architecture of a block of a 3D memory device capable of performing sub-page operations.

FIG. 9 is a timing diagram illustrating timing waveforms associated with interleaved sub-page operations in an example 3D memory device.

FIG. 10 is a chart illustrating a set of example configurations for a 3D memory device.

FIG. 11 is an example architecture for a set of blocks in a 3D memory device.

FIG. 12 is a timing diagram illustrating timing for a set of commands associated with non-adjacent wordline stripes in a 3D memory device.

FIG. 13 is a timing diagram illustrating timing for a set of commands associated with adjacent wordline stripes in a 3D memory device having local latches.

FIG. 14 is a timing diagram illustrating timing for a set of commands associated with different banks in a 3D memory device.

FIG. 15 illustrates an example embodiment of a memory module having a plurality of 3D memory devices.

### DETAILED DESCRIPTION

A 3D memory device includes a plurality of mats that each include a memory array stacked over logic circuitry supporting operations of the memory array. The logic circuitry includes a local column decoder under the memory array for selecting one or more local column select lines associated with a memory operation. The logic circuitry furthermore includes one or more selectable global array data bus redrivers for receiving global data signals from a set of global data signal buses, selecting one of the global data signal buses, and amplifying signals between the selected global data signal bus and a local data signal bus that communicates the data signals to and from the memory array. The 3D memory device supports concurrent sub-page accesses which may be interleaved for efficient memory operations.

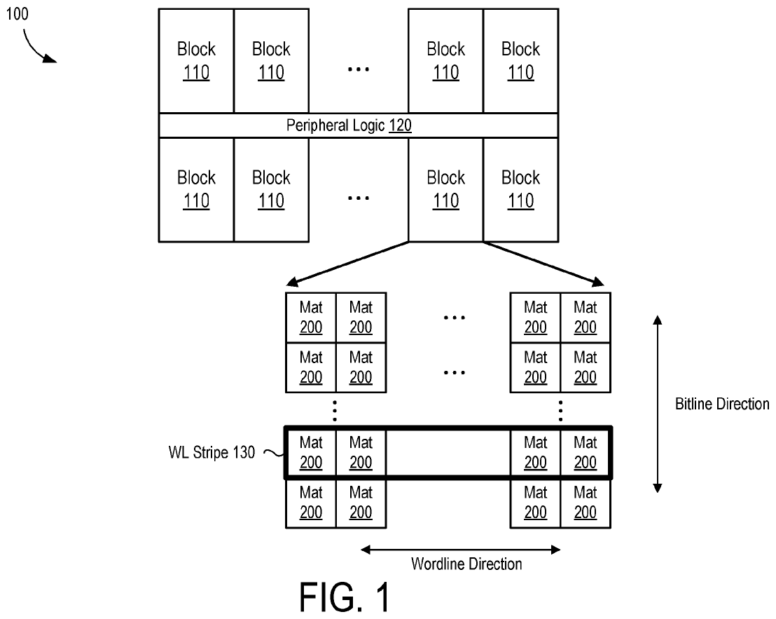

FIG. 1 illustrates an example architecture of a memory device 100. The memory device 100 is organized into a set of blocks 110 that each interface with peripheral logic 120 supporting various memory operations. Each block 110 comprises an array of mats 200 that each include an individual array of memory cells and supporting logic. The mats 200 have a 3D architecture in which at least some of the supporting logic is in a logic layer underneath the memory array. The memory arrays may be planar arrays (i.e., a single layer over the logic layer) or 3D memory arrays (i.e., multiple layers of memory cells stacked over the logic layer). A wordline stripe 130 represents a row of mats 200 within a block 110. The width of the wordline stripe 130 (i.e., number of cells in a single row spanning all mats 200) represents a page width associated with the block 110.

In an example embodiment, the memory device 100 comprises a 16 Gb DRAM device organized into 16 512 Mb blocks 110. The blocks 110 each comprise 64 k wordlines and a 1 kB page width, organized into a 49×8 array of mats 200. The mats 200 may comprise 1300b×1024b memory cell arrays and associated supporting logic. Alternative embodiments may include different mat and/or block sizes to accommodate different memory device sizes and/or architectures.

A block 110 may comprise the physical architecture for a bank of memory. Thus, in the architecture described, memory operations logically associated with a particular bank may be physically performed in association with a block 110.

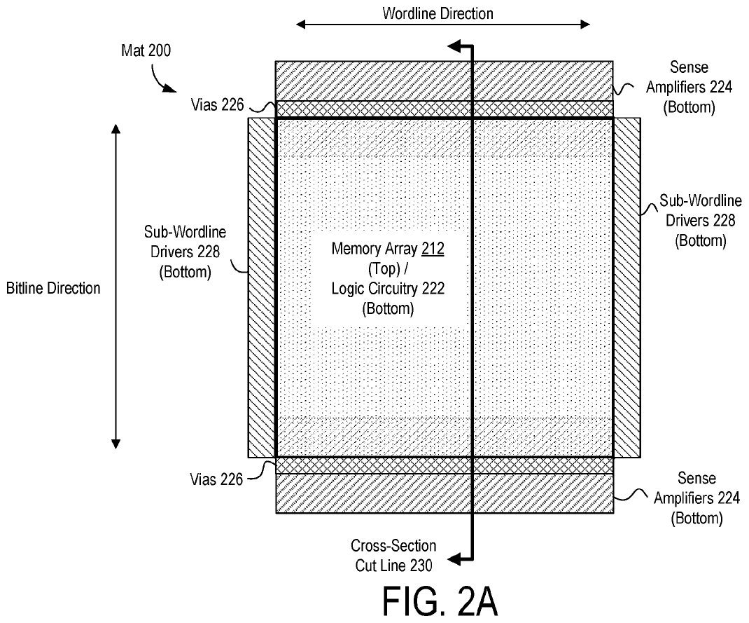

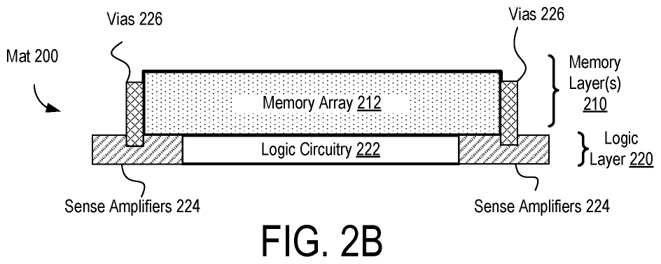

FIG. 2A illustrates a planar view of an individual mat 200 for a 3D memory device 100 and FIG. 2B illustrates a cross-sectional view of the mat 200 across the cut line 230. The mat 200 comprises a 3D structure having one or more memory arrays 212 in a memory layer 210 stacked over a logic layer 220. The logic layer 220 includes sense amplifiers 224, sub-wordline drivers 228, and/or other logic circuitry 222. The memory array 212 may comprise a single planar array of memory cells or multiple planar arrays of memory cells organized in a 3D architecture. Logic circuitry 222 comprises transistors and wiring levels below the memory array 212 and there might also be wiring levels above the memory array 212. Vias 226 connect the logic layer 220 to the memory array 212 and the wiring levels above the memory array 212. Connections to the memory array 212 may include connections of the sense amplifiers 224 to the bitlines and the sub-wordline drivers 228 to the wordlines. Connections to wiring levels above the memory array and through them to other supporting circuits outside of the memory array may include global array data lines and column select lines, described in further detail below. The logic circuitry 222 is at least partially positioned directly under the memory array 212. The sense amplifiers 224 and sub-wordline drivers 228 may be positioned in peripheral regions of the mat 200 outside the logic circuitry 222. The sense amplifiers 224 may be outside the edges of the memory array 212 or fully or partly underneath the memory array 212.

In an embodiment, the memory layer 210 and logic layer 220 are formed using monolithic technology in which or more memory arrays 212 are stacked over the logic layer 220 on a single substrate. In another embodiment, the memory layer 210 and the logic layer 220 are formed on separate substrates and die bonded together. In some embodiments, the memory layer 210 may include multiple memory arrays 212 each formed on separate substrates that are die bonded together.

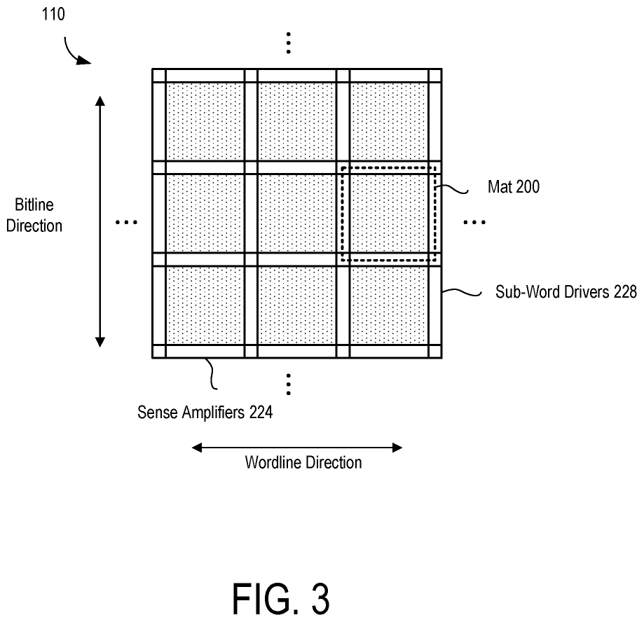

FIG. 3 illustrates a planar view of an example physical layout of a section of a block 110 comprising a plurality of mats 200. In this architecture, rows of sense amplifiers 224 in the logic layer 220 run in one direction in between adjacent mats 200 and columns of sub-wordline drivers 228 in the logic layer 220 run in a perpendicular direction in between adjacent mats 200. Memory arrays 212 in adjacent mats 200 may share sub-wordline drivers 228 and/or sense amplifiers 224.

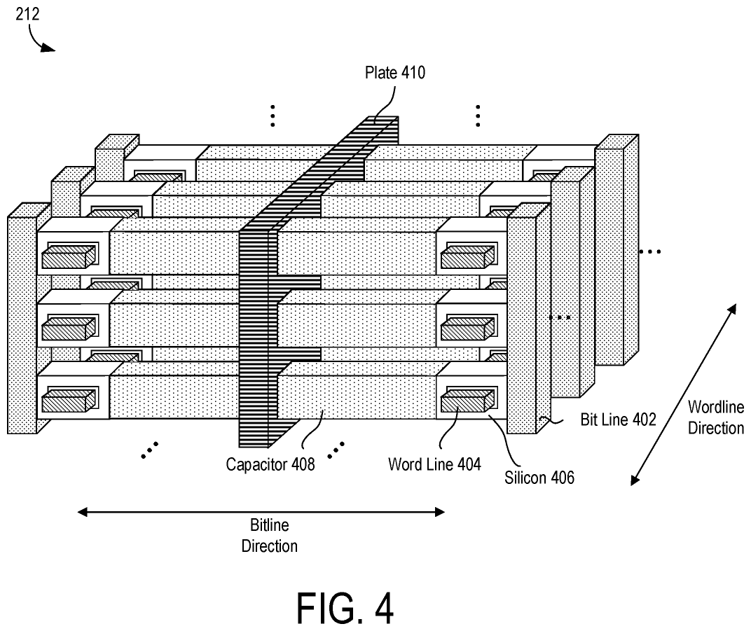

FIG. 4 illustrates an example of a 3D architecture for a memory array 212 of DRAM cells. In this example architecture, the long axes of the capacitors 408 of each memory cell are oriented horizontally (parallel to the substrate) adjacent to the access transistors in the silicon 406. Bitlines 402 run vertically (perpendicular to the substrate) and couple to the sense amplifiers 224 in the logic layer 210. The bitlines 402 also connect horizontally on a metal layer below the memory array 212 and above the logic layer 210 in a direction consistent with the illustrated bitline direction. The wordlines 404 run horizontally (parallel to the substrate and perpendicular to the long axes of the capacitors) and connect to the sub-wordline drivers 228 through peripheral vias (not shown). A plate 410 separates capacitors 408 of adjacent cells. FIG. 4 represents just one possible architecture for a memory array 212. Many other architectures are possible that can operate consistently with the techniques described herein.

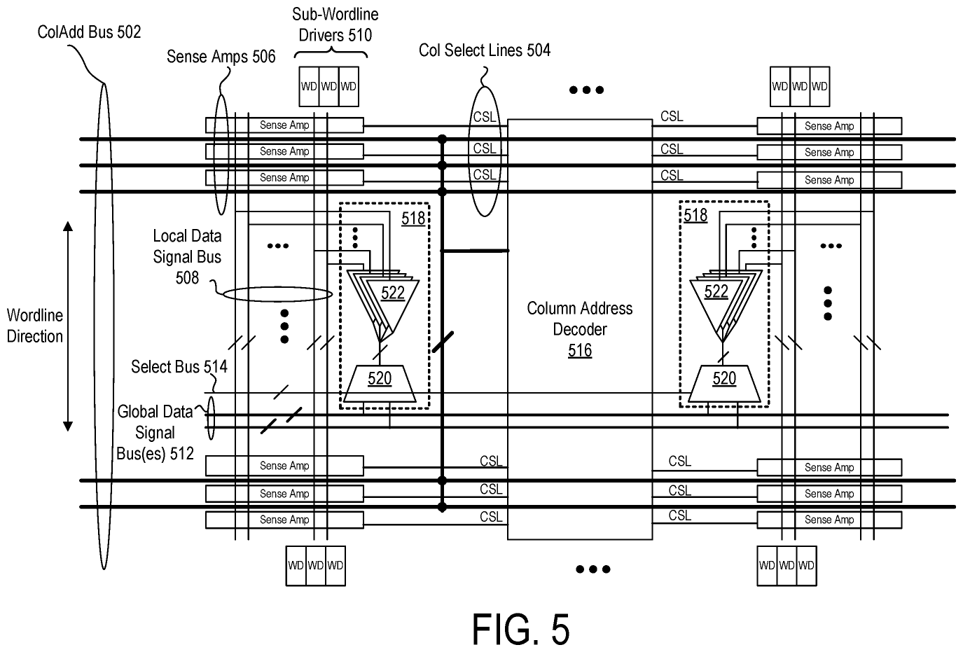

FIG. 5 illustrates an example architecture for a logic layer 220 of a mat 200 The logic layer 220 of the mat 200 includes a column address bus 502, a plurality of column select lines 504, a set of sense amplifiers 506, a local data signal bus 508, a plurality of sub-wordline drivers 510, a set of global data signal buses 512, a select bus 514, a column address decoder 516, and one or more selectable global array bus redrivers 518 which each include a switching circuit 520 and a set of redriving amplifiers 522.

The column address decoder 516 receives a column address associated with a memory operation via the column address bus 502 and decodes the column address to select one or more of the column select lines 504. The selected column select lines 504 are coupled to activate respective sense amplifiers 506 as described further below. The range of column addresses may be smaller than the number of column select lines 504. In this case, each unique column address concurrently selects multiple column select lines 504. For example, a 5-bit column address bus 502 enables 32 unique addresses that each concurrently select four different column select lines 504 out of a total of 128 column select lines 504. In other embodiments, a different number of column select lines 504 and/or different column address bus width may be employed depending on the architecture of the memory array 212 and the desired number of concurrently selectable column select lines 504.

The sub-wordline drivers 510 are coupled to respective wordlines 404 of the memory array 212. The sub-wordline drivers 510 operate to activate the memory cells in the corresponding wordline 404 in response to a memory operation associated with the wordline 404. When a wordline 404 is activated, the memory cells in the wordline 404 are coupled to the sense amplifiers 506 (via respective bitlines 402). The active column select lines 504 (selected by the column address) select corresponding sense amplifiers 506 for coupling to the local data signal bus 508 during the memory operation. For example, during a read operation, one or more selected sense amplifiers 506 sense and amplify the voltage on the corresponding bitlines 402 to read respective values from the memory cells of the active wordline 404 and output the values to the corresponding local data signal lines of the local data signal bus 508. During a write operation, selected sense amplifiers 506 sense and amplify the voltage on the local data signal bus 508 and output the values to the corresponding bitlines 402 to write to the selected memory cells of the active wordline 404.

The selectable global array bus redriver 518 interfaces between the local data signal bus 508 and the global data signal buses 512. The switching circuit 520 selects between two or more of the global data signal buses 512 and couples the selected global data signal bus 512 to the set of redriving amplifiers 522. The set of redriving amplifiers 522 amplify signals between the switching circuit 520 and the local data signal bus 508. In an embodiment, the global data signal bus 512 comprises a set of single-ended signal lines and the local data signal bus 508 comprises differential pairs of signal lines. The redriving amplifiers 522 convert between the single-ended signals of the global data signal bus 512 and the differential signals of the local data signal bus 508. Although not expressly shown in FIG. 5, the redriving amplifiers 522 may amplify signals in both directions between the local data signal bus 508 and the switching circuit 520. For example, in a write operation, the switching circuit 520 selects between write data on two or more global data signal buses 512, the redriving amplifiers 522 amplify the selected data to generate data signals on the local data signal bus 508, and the local data signal bus 508 communicates the write data to the respective sense amplifiers 506 for writing to the memory cells selected by the column select lines 504 and sub-wordline drivers 510. In a read operation, the local data signal bus 508 communicates data from the selected sense amplifiers 506 to the redriving amplifiers 522, the redriving amplifiers 522 amplify the read data, and the switching circuit 520 outputs the amplified read data to a selected global data signal bus 512 selected between the two or more global data signal buses 512. A select bus 514 controls switching of the switching circuit 520 to select between the available global data signal buses 512.

In an embodiment, a mat 200 includes two selectable global array bus redrivers 518 that are each coupled to the same global data signal buses 512 but are coupled to different lines of the local data signal bus 508. For example, in an architecture having two 32-bit global data signal buses 512, each selectable global array bus redriver 518 may be coupled to 16 differential local data signal lines pairs of the local data signal bus 508.

In an embodiment, the two selectable global array bus redrivers 518 of a mat 200 are arranged on opposite sides of the column address decoder 416. The sense amplifiers 506 of the mat 200 are similarly arranged in two rows on opposite sides of the column address decoder 416. The column address bus 502 and global data signal buses 512 may run perpendicular to the local data signal buses 508. The lines of the column address bus 502 and the global data signal buses 512 in the mat 200 may be routed in between the sense amplifiers 506 to the vias where they connect to the long wires across a block of mats, e.g., block 110 in FIG. 1.

In an embodiment, at least the column address decoder 516 and the selectable global array bus redrivers 518 are located in the logic layer 220 directly under the memory array 212. Furthermore, at least a portion of the global data signal buses 512, local data signal buses 508 and column address bus 502 may run directly under the memory array 212.

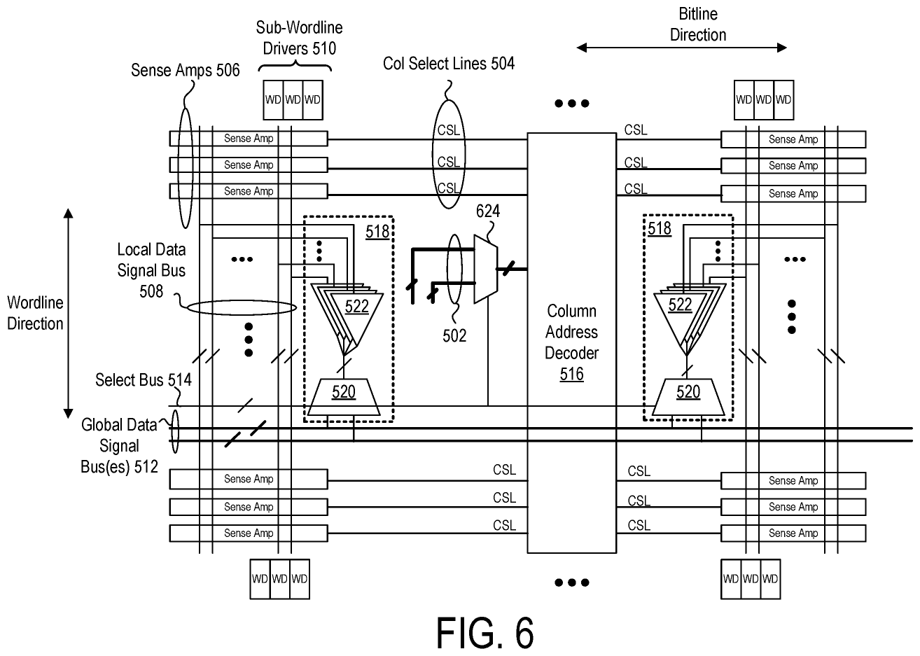

FIG. 6 illustrates an embodiment of the mat 200 having two independent column address buses 502 instead of a single column address bus 502. The routing of the individual column address lines are omitted from FIG. 6 for clarity, but may be routed similarly to the column address lines in FIG. 5. In this embodiment, a column address switching circuit 624 selects between the multiple column address buses 502 at the input to the column address decoder 516. In an embodiment, the column address switching circuit 624 may be controlled by the same select bus 514 as the switching circuit 520 of the selectable global array bus redrivers 518. For example, in one embodiment, a first column address bus 502 is selected when a first global data signal bus 512 is selected and a second column address bus 502 is selected when a second global data signal bus 512 is selected. In other embodiments, the mat 200 may include four or more different selectable column address buses.

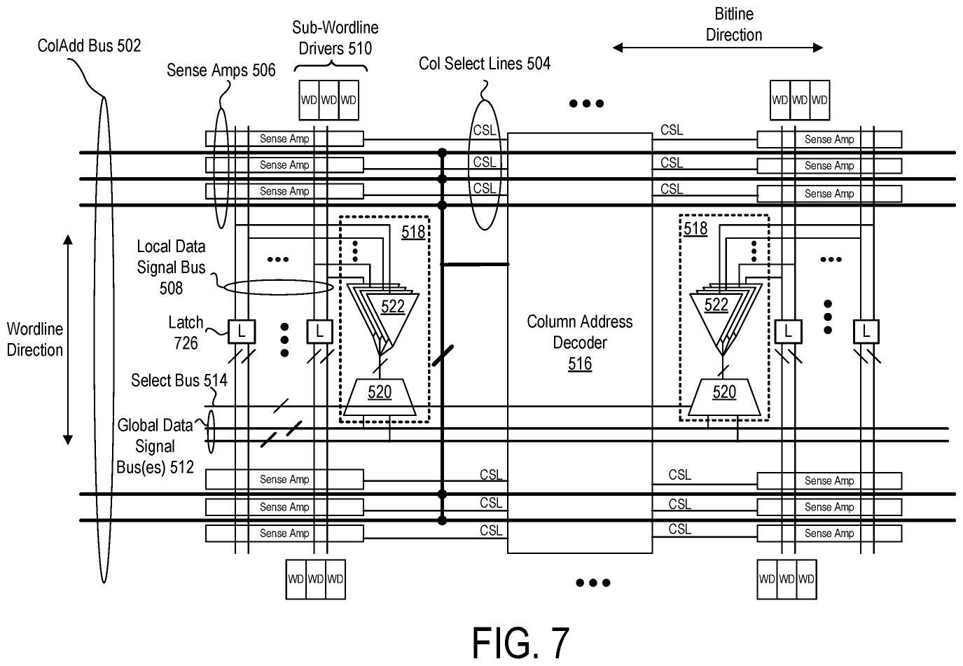

FIG. 7 illustrates an embodiment of the mat 200 that includes a row of latches 726 under the memory array 212 for locally buffering signals to and from the sense amplifiers 506. In an embodiment, the latches 726 may be physically placed in a stripe parallel to and adjacent to the stripe of sense amplifiers 506. The latches 726 enable interleaving of memory operations between adjacent wordline stripes sharing the sense amplifiers 506 for more efficient operations. For example, in a read operation, read data may be read from the sense amplifiers 506 to the latches 726 during a first part of a memory cycle and the sense amplifiers 506 may then be used by an adjacent wordline stripe during a second part of the same memory cycle, or vice versa. In a write operation, the write data may be stored in the latches 726 while sense amplifiers 506 are occupied with a memory operation associated with the adjacent wordline stripe during a first part of a memory cycle and then written from the latches 726 to the sense amplifiers 506 during the second part of the memory cycle or vice versa.

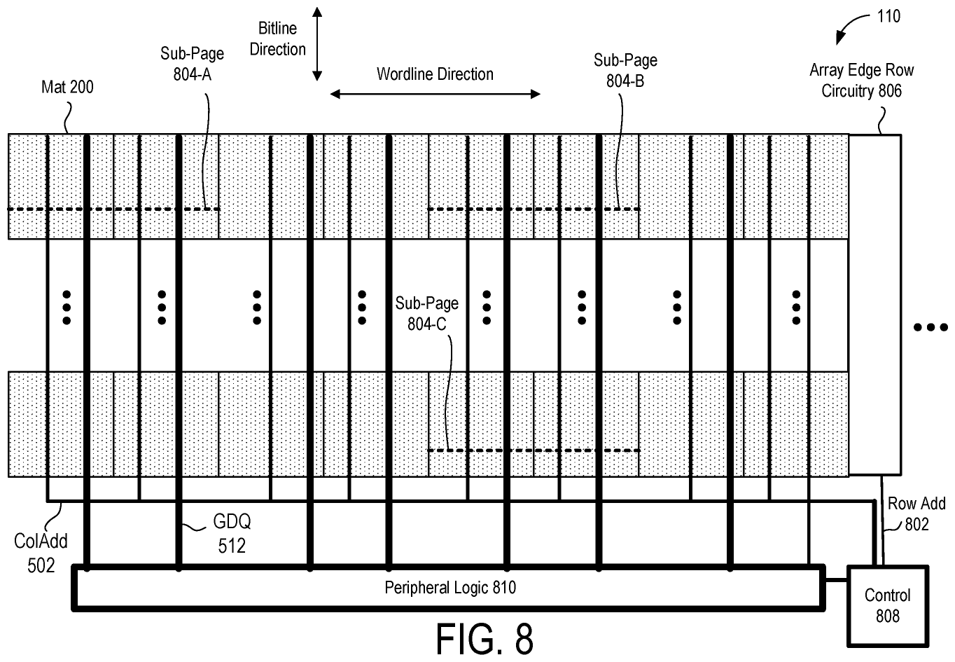

FIG. 8 illustrates an example embodiment of a layout for a block 110 of a 3D memory device 100 that enables sub-page operations. The block 110 includes a set of mats 200 arranged in a grid. Peripheral logic 810 includes a bus controller that controls respective global data signal buses (GDQ) 512 that are shared within a column of mats 200. The peripheral logic 810 may furthermore control other supporting functions of the block 110 such as, for example, error detection and/or correction, data muxing/de-muxing, and interfacing with an external memory controller. An address controller 808 controls one or more shared column address buses 502 that runs to each mat 200 via a set of column address lines for each column of mats 200. The address controller 808 furthermore controls array edge row circuitry 806 via a row address bus 802. The array edge row circuitry 806 controls the sub-wordline drivers 510 to activate rows of memory cells in the rows of mats 200. Each mat 200 may include a local column address decoder 516 and one or more selectable global array bus redrivers 518 as described above.

The described architecture enables performing different memory operations concurrently on two or more sub-pages that each comprise only a subset of cells from the full page. Concurrent operations may be performed between sub-pages that are horizontally separated in the same page (e.g., sub-pages 804-A, 804-B) or sub-pages that are vertically separated in the same mat columns (e.g., sub-pages 804-B, 804-C). In the illustrated embodiment, example sub-pages 804 each comprise the subset of memory cells spanning two adjacent mats 200 of a page. Concurrent access to sub-page 804-A and sub-page 804-B that are horizontally separated can be enabled by independently controlling separate global data signal buses 512 to the mats 200 using separate or switched decoders and drivers in the peripheral logic 810. Concurrent access to vertically separated sub-pages (e.g., sub-pages 804-B, 804-C) in different mats 200 of the same mat column may be achieved by controlling the different mats 200 to access different global data signal buses 512 (based on the select bus 514).

In an embodiment, vertically adjacent wordline stripes may share a set of sense amplifiers 506 as described above. To avoid data loss, the peripheral logic 810 may allow concurrent access to vertically separated sub-pages 804 only when the sub-pages 804 are in non-adjacent wordline stripes. Therefore, the minimum time between accesses to neighboring wordline stripes in a bank (which may correspond to a physical block 110 in the architecture shown) may be longer than the minimum access time to non-neighboring wordline stripes. In embodiments having latches 726 that locally latch data in each mat 200 (e.g., as per FIG. 7), the above timing constraints are eliminated and the peripheral logic 810 may allow for concurrent sub-page accesses between adjacent wordline stripes in vertically separated mats 200.

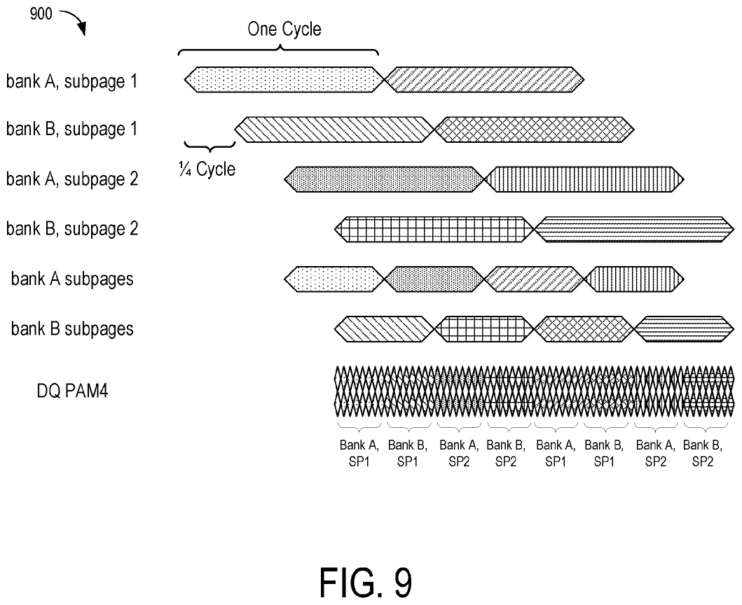

FIG. 9 is a timing diagram illustrating an example sequence of sub-page memory operations 900. In this embodiment, the memory device architecture enables concurrent access to up to two different banks and enables concurrent access to up to two different sub-pages within the same bank. Memory operations are interleaved to initiate a new operation every one-quarter cycle. For example, a controller may initiate memory operations associated with different sub-pages in the following sequence: bank A/sub-page 1, bank B/subpage 1, bank A/subpage 2, bank B/subpage 2. Operations involving different sub-pages in the same bank are separated by one-half cycle and operations between different sub-pages in different banks are separated by one-quarter cycle. In the illustrated embodiment, a PAM-4 (pulse amplitude modulation 4-level) format is used where each symbol represents 2 bits. Alternatively, a PAM-2 format may be used where each symbol represents a single bit.

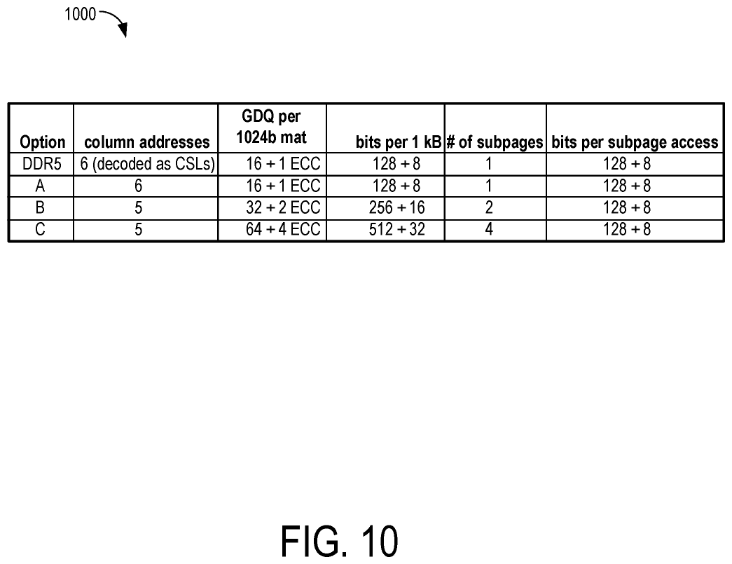

FIG. 10 is a chart 1000 illustrating various example configurations (e.g., options A, B, C) for a 3D memory device relative to a typical DDR5 configuration. In the DDR5 configuration, a typical device includes a 6-bit column address, which is globally decoded and distributed on 64 column select lines. Each mat is 1024b wide and communicates data over a data bus having 16 data lines and one ECC line. A wordline stripe of 8 mats comprises 1 kB pages and has 128 data lines and 8 ECC lines. For page operations accessing 128 bits and 8 ECC bits, each operation involves a full-page access (i.e., there is a single sub-page).

In a first example configuration of the described 3D memory device 100 (option A), the device 100 include a 6-bit column address (decoded locally) and 1024b wide mats 200 that each communicate over a global data signal bus having 16 data lines and one ECC line. For 1 kB pages, a wordline stripe spans 8 mats and has 128 data lines and 8 ECC lines. An operation accessing 128 bits and 8 ECC bits involves a full-page access.

In a second example configuration of the described 3D memory device 100 (option B), the device 100 includes a 5-bit column address (decoded locally) and 1024b wide mats 200 that each communicate over a global data signal bus having 32 data lines and two ECC lines. In this case, a wordline stripe spanning 8 mats (for 1 kB pages) has 256 data lines and 16 ECC lines. An operation accessing 128 bits and 8 ECC bits utilizes only half of the available data lines and ECC lines. The device 100 can enable concurrent access to two sub-pages (each comprising a 128b+8b access) using the techniques described above.

In a third example configuration of the described 3D memory device 100 (option C), the device 100 includes a 5-bit column address (decoded locally) and 1024b wide mats 200 that each communicate over a global data signal bus having 64 data lines and four ECC lines. In this case, a wordline stripe spanning 8 mats (for 1 kB pages) has 512 data lines and 32 ECC lines. An operation accessing 128 bits and 8 ECC bits utilizes only one quarter of the available data lines and ECC lines. The device 100 can enable concurrent access to four sub-pages (each comprising a 128b+8b access) using the techniques described above.

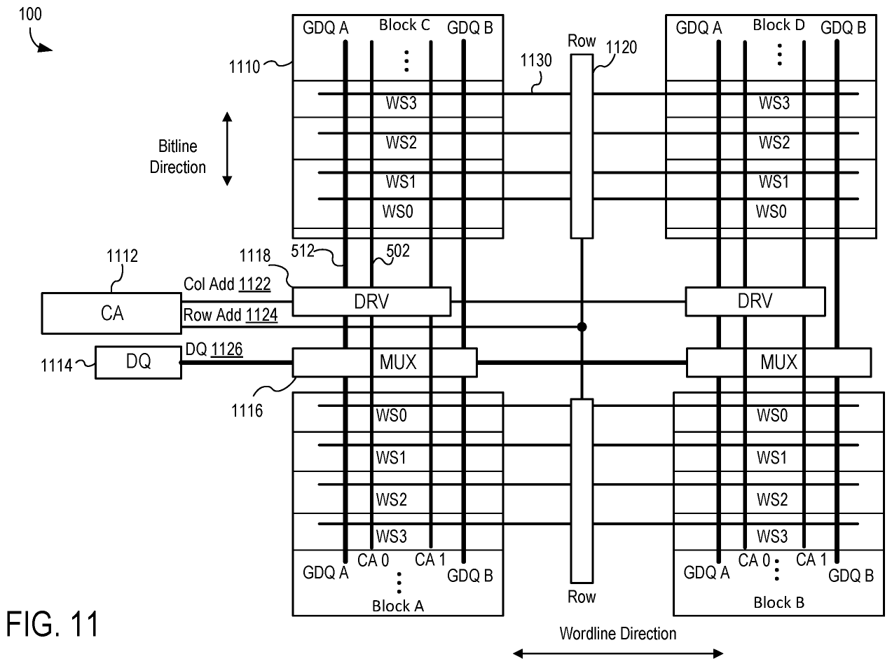

FIG. 11 illustrates an example architecture for a 3D memory device including a set of blocks 1110 that each comprise a set of wordline stripes (WSx) 1130 and supporting circuits. The supporting circuits include a command/address controller 1112, a data (DQ) driver 1114, a set of multiplexers 1116, a set of column address drivers 1118, and a set of row address drivers 1120.

The CA controller 1112 provides a column address 1122 and row address 1124 to the column address drivers 1118 and row address drivers 1120 respectively. In an embodiment, each column address driver 1118 drives the column address for a pair of vertically adjacent blocks 1110 while each row address driver 1120 drives the row addresses for a pair of horizontally adjacent blocks 1110. In this embodiment, there are two independent column address buses 502 per block 1110. The DQ driver 1114 controller communicates data to and from the global data signal buses 512 (e.g., GDQ A and GDQ B for each block 1110).

For clarity of illustration, individual mats 200 are not shown in FIG. 11. Furthermore, the global data signal buses 512 and column address buses 502 are shown as single pairs of lines for each block 1110. However, in practice a pair of global data signal buses 512 and column address buses 502 are provided to each mat 200 as described above.

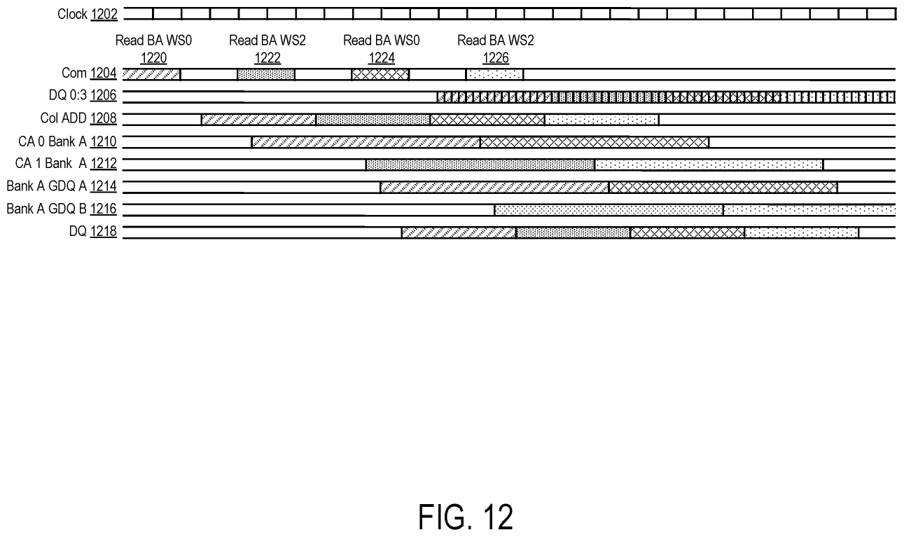

FIG. 12 is a timing diagram associated with read operations to non-adjacent word stripes in the same bank (which may correspond to a physical block 110) in a 3D memory device 100 having an architecture with two global data signal buses 512 and two column address buses 502 per mat 200 (such as the architecture of FIG. 11). In this example, a command signal 1204 shows sequential commands (relative to a clock signal 1202) including a first read 1220 from wordline stripe WS0, a first read 1222 from wordline stripe WS2, a second read 1224 from the wordline stripe WS0, and a second read 1226 from the wordline stripe WS2. All reads are directed to the same bank (bank A). Each command 1204 is followed by a correspond column address 1208 on the column address lines, which are issued in an interleaved pattern between the first column address bus 1210 (for the read commands associated with WS0) and the second column address bus 1212 (for the read commands associated with WS2). Shortly thereafter, the data associated with the respective commands is read onto the respective global data signal buses 1214, 1216. Here, the read data is similarly interleaved between the two available global data signal buses 1214, 1216 with the read data associated with WS0 utilizing a first global data signal bus 1214 and the read data associated with the WS2 utilizing the second global data signal bus 1216. The data is then output on the DQ bus 1218 for the bank and then to the external device DQ lines 1206. As can be seen, the dual column address buses 1210, 1212 and dual global data signal uses 1214, 1216 enable interleaved read commands between different non-adjacent wordline stripes (WS0, WS2) in the same bank to be executed with overlapping timing.

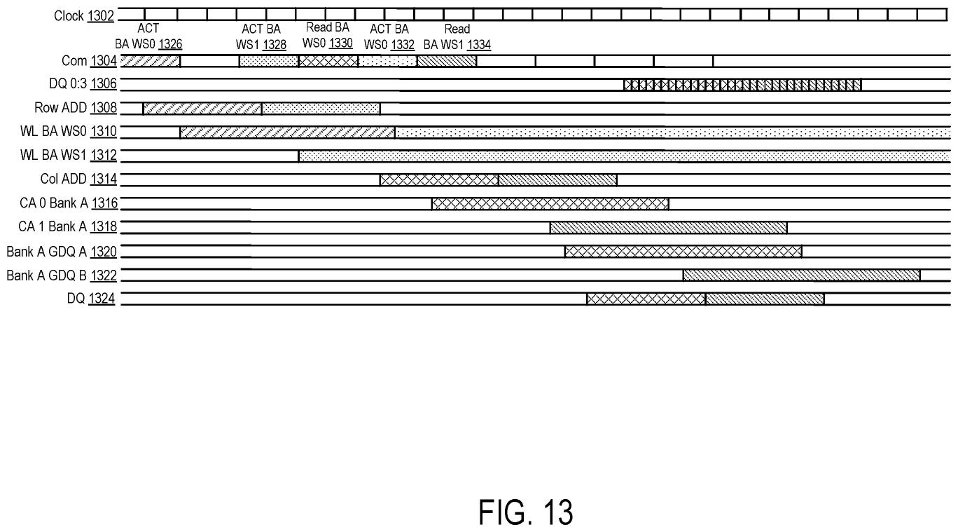

FIG. 13 is another timing diagram associated with a sequence of activate commands and read commands 1304 (relative to a clock 1302) associated with adjacent wordline stripes in the same bank (Bank A or “BA”, which may correspond to a single physical block 110 in the architecture described above). In this embodiment, the mats 200 include local latches (as in the embodiment of FIG. 7) to enable overlapping operations in adjacent wordline stripes without the timing constraints associated with shared sense amplifiers. In this sequence, the commands 1304 initially include consecutive activate commands 1326, 1328 associated with the adjacent wordline stripes WS0, WS1 followed by respective row addresses 1308. The data 1310 from the first activate command 1326 associated with WS0 is read into the sense amplifiers and then locally latched, which then enables the data 1312 from the second activate command 1328 associated with WS1 to be locally sensed. The data 1310 associated with WS0 remains locally stored until overwritten by a third activate command 1332 associated with the same wordline stripe WS0. Thus, at any time, the device 100 can locally store data from rows of adjacent wordline stripe even though they share sense amplifiers.

FIG. 13 also illustrates a sequence of read commands 1330, 1334 associated with the wordline stripe WS0, WS1 followed by respective column addresses 1314, which are interleaved onto different column address buses 1316, 1318. The read data is similarly interleaved on the global data signal buses 1320, 1322, output to the internal DQ lines 1324, and then to the external DQ lines 1306.

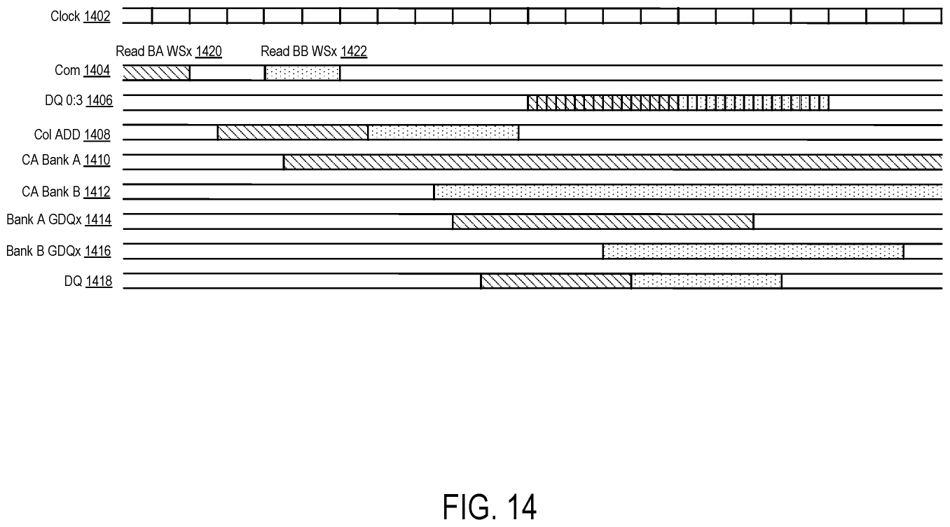

FIG. 14 is another timing diagram associated with a sequence of commands 1404 relative to clock 1402. In this example, the commands 1404 include read commands 1420, 1422 associated with different banks (bank A, bank B). The read commands 1420, 1422 are followed by respective column addresses 1408, which are interleaved on the respective column address buses 1410, 1412 for different banks (Bank A, Bank B). The read data is interleaved on respective global data signal buses 1414, 1416 for the different banks, output to the local DQ lines 1418, and then the external DQ lines 1406.

FIGS. 12-14 demonstrate that the described architectures can enable back-to-back accesses to different banks, back-to-back accesses to non-adjacent wordline stripes in the same bank, and/or back-to-back accesses to the same wordline stripes with the same or similar timing restrictions. In an embodiment, the controller may therefore schedule memory accesses without necessarily differentiating between bank groups and banks.

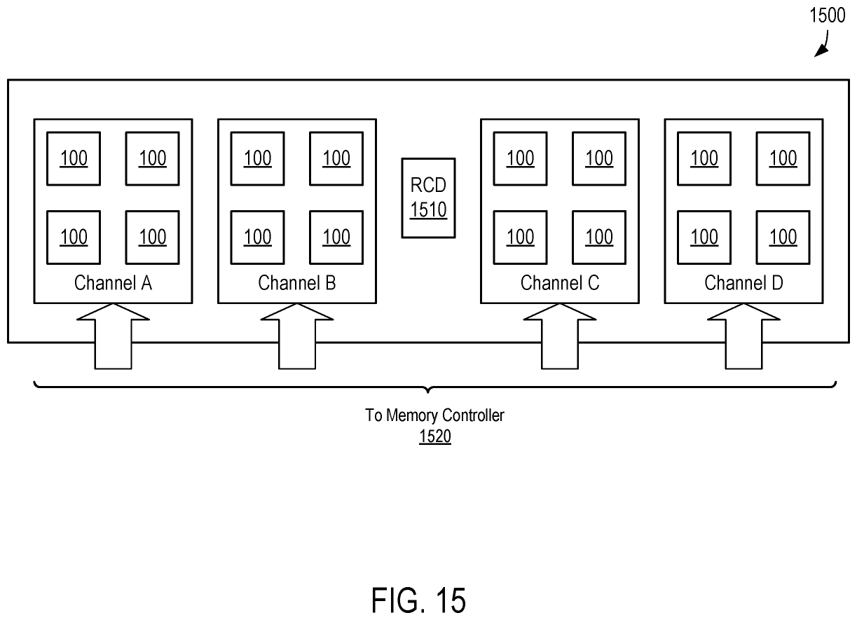

FIG. 15 illustrates an example embodiment of a memory module 1500 incorporating the 3D memory device 100 described above. The memory module 1500 includes a register clock driver (RCD) 1510 and a plurality of 3D memory devices 100 organized into channels. The RCD 1510 communicates command/address, clock, or other control signals (not shown) between a memory controller 1520 and the set of memory devices 100. In this example, the memory module 1500 comprises four channels (e.g., channels A-D) that may independently communicate with the memory controller 1520 and four memory devices 100 per channel. Alternative embodiments may include different numbers of channels or different numbers of memory devices 100 per channel.

Upon reading this disclosure, those of ordinary skill in the art will appreciate still alternative structural and functional designs and processes for the described embodiments, through the disclosed principles of the present disclosure. Thus, while embodiments and applications of the present disclosure have been illustrated and described, it is to be understood that the disclosure is not limited to the precise construction and components disclosed herein. Various modifications, changes and variations which will be apparent to those skilled in the art may be made in the arrangement, operation and details of the method and apparatus of the present disclosure herein without departing from the scope of the disclosure as defined in the appended claims.

What is claimed is:

1. A 3D memory device comprising:
a plurality of mats, each mat of the plurality of mats including a memory cell array;
logic circuitry disposed under the memory cell array in each mat, the logic circuitry including:
a plurality of column select lines to select a column of memory cells of a memory cell array of a corresponding mat;
a local data signal bus to communicate data to and from the memory cell array of the corresponding mat;
two or more global data signal buses to communicate data externally to and from the corresponding mat;
a column address decoder to select one or more of the plurality of column select lines of the corresponding mat; and
at least one selectable global array data bus redriver including a data bus selector circuit controllable by a select signal to select one of the global data signal buses for coupling to the local data signal bus, and a set of amplifiers to amplify data signals communicated between the selected global data signal bus and the local data signal bus.

2. The 3D memory device of claim 1, wherein the logic circuitry further includes:
a plurality of sense amplifiers at least partially under the memory cell array to sense data communicated between the memory cell array and the local data signal bus.

3. The 3D memory device of claim 2, wherein the plurality of sense amplifiers are shared between adjacent mats in a block of the 3D memory device.

4. The 3D memory device of claim 1, further comprising:
one or more column address buses to provide a column address to the column address decoder specifying the one or more column select lines; and
wherein the two or more global data signal buses and the one or more column address buses are shared between a column of mats in a block of the 3D memory device.

5. The 3D memory device of claim 1, wherein the plurality of mats are arranged into blocks, wherein each of the blocks has a page width spanning the mats in a row, and wherein the logic circuitry is configured to perform a first sub-page memory operation associated with a first sub-page comprising a first subset of a first row of memory cells having a sub-page width smaller than the page width, and prior to the first sub-page memory operation completing, initiating a second sub-page memory operation associated with a second sub-page comprising a second subset of a second row of memory cells having the sub-page width.

6. The 3D memory device of claim 5, wherein the second sub-page memory operation is initiated a fraction of a cycle time after the first sub-page memory operation.

7. The 3D memory device of claim 5, wherein the first sub-page includes memory cells in at least a first mat coupled to a first global array data signal bus and the second sub-page includes memory cells in at least a second mat coupled to a second global array data signal bus independent from the first global array data signal bus, wherein the logic circuitry further includes:
a bus controller coupled to the first global array data signal bus and the second global array data signal bus to control timing of the first sub-page operation and the second sub-page operation.

8. The 3D memory device of claim 5, wherein the first sub-page includes memory cells in at least a first mat and the second sub-page includes memory cells in at least a second mat having shared set of global array data signal buses with the first mat.

9. The 3D memory device of claim 8, wherein performing the first sub-page memory operation comprises controlling a select bus to control a selector circuit associated with the first mat to select a first bus of the shared global array data signal buses and a selector circuit associated with the second mat to select a second bus of the shared global array data signal buses.

10. The 3D memory device of claim 8, wherein a minimum delay between memory operations associated with neighboring mats sharing a set of sense amplifiers are longer than a minimum delay associated with memory operations associated with mats that do not share sense amplifiers.

11. The 3D memory device of claim 1, wherein the logic circuitry further includes for each mat:
a plurality of latches coupled to the local data signal bus to locally buffer data from a set of sense amplifiers shared with neighboring mats.

12. The 3D memory device of claim 1, wherein the logic circuitry further comprises:
a column address bus for transmitting a column address to the column address decoder that specifies the one or more column address lines.

13. The 3D memory device of claim 1, wherein logic circuitry further comprises:
at least two column address buses for independently transmitting respective selectable column addresses to the column address decoder; and
a column address bus selector circuit to select between the at least two column address buses to select the column address, wherein the selected column address specifies the one or more column select lines.

14. The 3D memory device of claim 1, wherein the local data signal bus comprises a set of differential paired signal lines and wherein the global data signal buses comprise single-ended signal lines, wherein the set of amplifiers convert between the differential paired signal lines and the single-ended signal lines.

15. The 3D memory device of claim 1, wherein the 3D memory device comprises:
a substrate;
a logic layer on the substrate including the logic circuitry; and
at least one memory cell layer including the plurality of mats stacked over the logic layer.

16. The 3D memory device of claim 1, wherein the plurality of mats are on a first die and wherein the logic circuitry is on a second die bonded to the first die.

17. A memory module comprising:
a plurality of 3D memory devices mounted to a printed circuit board, each of the plurality of 3D memory devices comprising a plurality of mats, each of the plurality of mats including a memory cell array and logic circuitry under the memory cell array in a stacked configuration, wherein the logic circuitry for each of the plurality of mats includes:
a plurality of column select lines to select a column of memory cells of a memory cell array of a corresponding mat;
a local data signal bus to communicate data to and from the memory cell array of the corresponding mat;
two or more global data signal buses to communicate data externally to and from the corresponding mat;
a column address decoder to select one or more of the plurality of column select lines of the corresponding mat; and
at least one selectable global array data bus redriver including a data bus selector circuit controllable by a select signal to select one of the global data signal buses for coupling to the local data signal bus, and a set of amplifiers to amplify data signals communicated between the selected global data signal bus and the local data signal bus.

18. The memory module of claim 17, wherein the plurality of mats are arranged into blocks, wherein each of the blocks has a page width spanning the mats in a row, and wherein the logic circuitry is configured to perform a first sub-page memory operation associated with a first sub-page comprising a first subset of a first row of memory cells having a sub-page width smaller than the page width, and prior to the first sub-page memory operation completing, initiating a second sub-page memory operation associated with a second sub-page comprising a second subset of a second row of memory cells having the sub-page width.

19. A logic circuit for a 3D memory device comprising:
a logic layer organized into a plurality of mats to interface with respective memory cell arrays that are to be stacked with the logic layer in a stacked configuration, the logic layer comprising:
a plurality of column select lines to select a column of memory cells of a memory cell array of a corresponding mat;
a local data signal bus to communicate data to and from the memory cell array of the corresponding mat;
two or more global data signal buses to communicate data externally to and from the corresponding mat;
a column address decoder to select one or more of the plurality of column select lines of the corresponding mat; and
at least one selectable global array data bus redriver including a data bus selector circuit controllable by a select signal to select one of the global data signal buses for coupling to the local data signal bus, and a set of amplifiers to amplify data signals communicated between the selected global data signal bus and the local data signal bus.

20. The logic circuit of claim 19, wherein the plurality of mats are arranged into blocks, wherein each of the blocks has a page width spanning the mats in a row, and wherein the logic layer is configured to perform a first sub-page memory operation associated with a first sub-page comprising a first subset of a first row of memory cells having a sub-page width smaller than the page width, and prior to the first sub-page memory operation completing, initiating a second sub-page memory operation associated with a second sub-page comprising a second subset of a second row of memory cells having the sub-page width.
